(19) United States
(12) Patent Application Publication
(10) Pub. No.: US 2024/0071894 A1
(43) Pub. Date: Feb. 29, 2024

(54) PACKAGED INTEGRATED CIRCUIT HAVING ENHANCED ELECTRICAL INTERCONNECTS THEREIN

(71) Applicant: Samsung Electronics Co., Ltd., Suwon-si (KR)

(72) Inventors: Hyeonjeong Hwang, Suwon-si (KR); Dongkyu Kim, Suwon-si (KR); Kyounglim Suk, Suwon-si (KR); Hyeonseok Lee, Suwon-si (KR)

(21) Appl. No.: 18/335,336

(22) Filed: Jun. 15, 2023

(30) Foreign Application Priority Data
Aug. 31, 2022 (KR) 10-2022-0110325

(51) Int. Cl. H01L 23/498

(52) U.S. Cl. CPC H01L 23/49838; H01L 23/49811; H01L 23/49822; H01L 24/16; H01L 2224/16227

(57) ABSTRACT

A packaged integrated circuit includes a redistribution layer having a plurality of electrically conductive vias extending at least partially therethrough, and a plurality of lower pads electrically connected to corresponding ones of the plurality of electrically conductive vias. A semiconductor chip is provided on the redistribution layer, and external connection terminals are provided, which electrically contact corresponding ones of the plurality of lower pads within the redistribution layer. Each of the plurality of lower pads includes: (i) a lower under-bump metallization (UBM) layer in contact with a corresponding external connection terminal, and (ii) an upper UBM layer extending on and contacting the lower UBM layer. In addition, an upper surface of the lower UBM layer has a greater lateral width dimension relative to an upper surface of the upper UBM layer, which contacts a corresponding electrically conductive via.

### REFERENCE TO PRIORITY APPLICATION

This application claims priority under 35 U.S.C. § 119 to Korean Patent Application No. 10-2022-0110325, filed Aug. 31, 2022, the disclosure of which is hereby incorporated herein by reference.

### BACKGROUND

The inventive concept relates to integrated circuit packaging technology and, more particularly, packaging technology that supports fan-out type electrical interconnects between chips therein and the package.

Owing to the rapid development of the electronics industry, much smaller and lighter electronic products and equipment have been developed to satisfy users' demands. Accordingly, semiconductor devices, which are often core components of electronic products, are required to be highly integrated. In addition, small and multifunctional semiconductor devices are needed along with the development of mobile products.

### SUMMARY

The inventive concept provides an integrated circuit package having a redistribution insulating layer therein with improved electrical performance and reliability.

The inventive concept provides an integrated circuit package in which the structural reliability of a lower pad of a redistribution layer is improved.

According to an embodiment of the inventive concept, there is provided a packaged integrated circuit having a redistribution layer therein, which includes a plurality of conductive lines, a plurality of conductive vias (each connected to at least one of the plurality of conductive lines), and a plurality of lower pads (each connected to one of the plurality of conductive vias). A semiconductor chip is provided on the redistribution layer, and an external connection terminal is provided, which is attached to the plurality of lower pads of the redistribution layer. Each of the plurality of lower pads includes a lower under-bump metallization (UBM) layer provided in contact with the external connection terminal and an upper UBM layer extending on the lower UBM layer. Advantageously, a first width, which is a horizontal width of the upper UBM layer, is equal to or less than a second width, which is a horizontal width of an upper surface of the lower UBM layer.

According to another embodiment of the inventive concept, there is provided a packaged integrated circuit (a/k/a semiconductor package) having a redistribution layer therein, which includes a plurality of conductive lines, a plurality of conductive vias each connected to at least one of the plurality of conductive lines, a plurality of lower pads each connected to one of the plurality of conductive vias, and a plurality of redistribution insulating layers. A semiconductor chip is provided on the redistribution layer, and a plurality of external connection terminals are provided, which are attached to the plurality of lower pads of the redistribution layer. Each of the plurality of lower pads is disposed in a lowermost redistribution insulating layer of the plurality of redistribution insulating layers between one of the plurality of conductive vias and one of the plurality of external connection terminals. In addition, each of the plurality of lower pads includes a lower UBM layer provided in contact with one of the plurality of external connection terminals and an upper UBM layer disposed on the lower UBM layer. Advantageously, a first width, which is a horizontal width of the upper UBM layer, is equal to or less than a horizontal width of an upper surface of the lower UBM layer.

According to another embodiment of the inventive concept, there is provided a packaged integrated circuit having a first redistribution layer therein, which includes a plurality of first conductive lines, a plurality of first conductive vias each connected to at least one of the plurality of first conductive lines, a plurality of first lower pads each connected to one of the plurality of first conductive vias, and a plurality of lower redistribution insulating layers. A semiconductor chip is provided on the first redistribution layer. Connection structures are provided, which are arranged on the first redistribution layer and spaced apart from the semiconductor chip in a horizontal direction. A second redistribution layer is provided, which extends on the connection structures and includes a plurality of second conductive lines and a plurality of second conductive vias each connected to at least one of the plurality of second conductive lines. A plurality of external connection terminals are provided, which are attached to the plurality of first lower pads of the first redistribution layer. Each of the plurality of first lower pads extends within a lowermost lower redistribution insulating layer of the plurality of lower redistribution insulating layers between one of the plurality of first conductive vias and one of the plurality of external connection terminals. In addition, each of the plurality of first lower pads includes a lower UBM layer provided in contact with one of the plurality of external connection terminals and an upper UBM layer disposed on the lower UBM layer. The lower UBM layer has a tapered shape with a downwardly decreasing horizontal width; a first width, which is a horizontal width of the upper UBM layer is equal to or less than a second width, which is a horizontal width of an upper surface of the lower UBM layer.

### BRIEF DESCRIPTION OF THE DRAWINGS

Embodiments will be more clearly understood from the following detailed description taken in conjunction with the accompanying drawings in which:

FIG. 1A is a cross-sectional view illustrating a packaged integrated circuit according to embodiments, and FIG. 1B is an enlarged cross-sectional view illustrating a portion A in FIG. 1A according to embodiments. FIG. 1C is a bottom view illustrating a lower pad according to embodiments;

FIG. 2 is an enlarged cross-sectional view illustrating a portion A of FIG. 1A according to embodiments;

FIG. 3 is a cross-sectional view illustrating a packaged integrated circuit according to embodiments;

FIG. 4 is a cross-sectional view illustrating a packaged integrated circuit according to embodiments;

FIG. 5 is a cross-sectional view illustrating a packaged integrated circuit according to embodiments;

FIGS. 6A to 6H are cross-sectional views illustrating a method of manufacturing a packaged integrated circuit according to embodiments;

FIG. 7 is a cross-sectional view illustrating a package-on-package having a packaged integrated circuit according to embodiments;

FIG. 8 is a cross-sectional view illustrating a package-on-package having a packaged integrated circuit according to embodiments;

FIG. 9 is a cross-sectional view illustrating a package-on-package having a packaged integrated circuit according to embodiments; and

FIG. 10 is a cross-sectional view illustrating a package-on-package having a packaged integrated circuit according to embodiments.

### DETAILED DESCRIPTION OF EMBODIMENTS

Hereinafter, embodiments of the technical idea of the inventive concept will be described with reference to the accompanying drawings. In the drawings, like reference numerals refer to like elements, and overlapping descriptions thereof will be omitted.

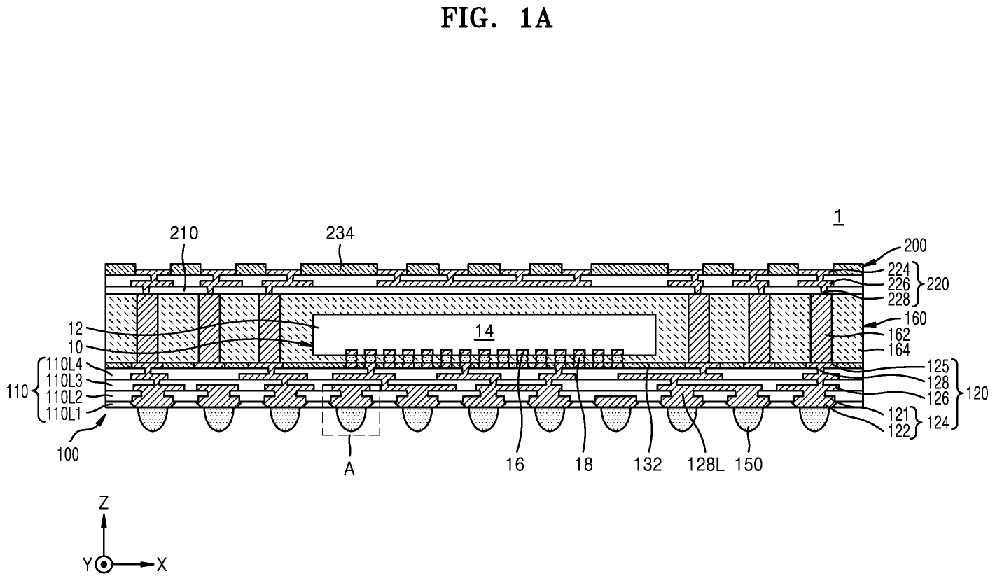

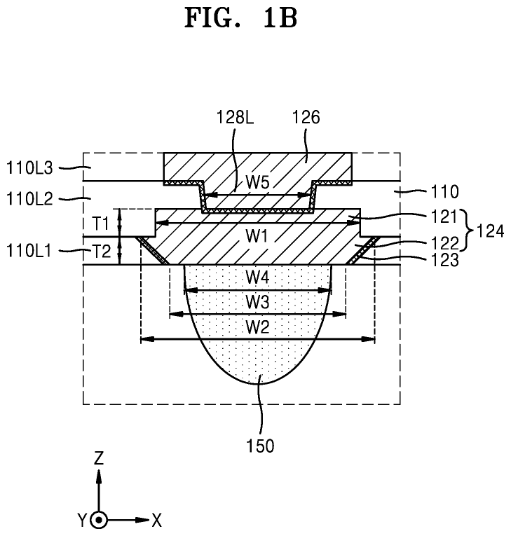

FIG. 1A is a cross-sectional view illustrating a packaged integrated circuit 1 according to embodiments, FIG. 1B is an enlarged cross-sectional view illustrating a portion A in FIG. 1A according to embodiments, and FIG. 1C is a bottom view illustrating a lower pad according to embodiments. Referring to FIGS. 1A to 1C, the packaged integrated circuit 1 may include a semiconductor chip 10, a lower redistribution layer 100, an extended layer 160, connection structures 162, and an upper redistribution layer 200. The extended layer 160 may surround the semiconductor chip 10. The semiconductor chip 10, the extended layer 160, and the connection structures 162 are arranged on the lower redistribution layer 100. In addition, an upper redistribution layer 200 is disposed on the semiconductor chip 10, the extended layer 160, and the connection structures 162. Although FIG. 1A illustrates that the packaged integrated circuit 1 includes one semiconductor chip 10, this is a non-limiting example. In some embodiments, the packaged integrated circuit 1 may include a plurality of semiconductor chips 10.

The packaged integrated circuit 1 may be a fan-out packaged integrated circuit in which the horizontal width and the horizontal area of the lower redistribution layer 100 are respectively greater than the horizontal width and the horizontal area of the footprint of the semiconductor chip 10, and the horizontal width and the horizontal area of the upper redistribution layer 200 are respectively greater than the horizontal width and the horizontal area of the footprint of the semiconductor chip 10. For example, when the packaged integrated circuit 1 includes one semiconductor chip 10, the horizontal width and the horizontal area of the lower redistribution layer 100 may be respectively greater than the horizontal width and the horizontal area of the semiconductor chip 10, and the horizontal width and the horizontal area of the upper redistribution layer 200 may be respectively greater than the horizontal width and the horizontal area of the semiconductor chip 10. In some embodiments, the horizontal width and the horizontal area of the lower redistribution layer 100 may be respectively equal to the horizontal width and the horizontal area of the upper redistribution layer 200. In some embodiments, sidewalls corresponding of the lower redistribution layer 100, the extended layer 160, and the upper redistribution layer 200 may be coplanar.

The semiconductor chip 10 may include: a semiconductor substrate 12 having a semiconductor device 14 formed on an active surface of the semiconductor substrate 12; and a plurality of chip connection pads 16 arranged on the active surface of the semiconductor substrate 12. In some embodiments, when the packaged integrated circuit 1 is a lower package of a package-on-package (PoP), the packaged integrated circuit 1, the semiconductor chip 10, the semiconductor substrate 12, the semiconductor device 14, and the chip connection pads 16 may be respectively referred to as a first packaged integrated circuit, a first semiconductor chip, a first semiconductor substrate, and a first semiconductor device, and first chip connection pads, or may be respectively referred to as a lower packaged integrated circuit, a lower semiconductor chip, a lower semiconductor substrate, a lower semiconductor device, and lower chip connection pads.

The semiconductor substrate 12 may include, for example, a semiconductor material such as silicon (Si). Alternatively, the semiconductor substrate 12 may include a semiconductor element such as germanium (Ge), or may include a compound semiconductor such as silicon carbide (SiC), gallium arsenide (GaAs), indium arsenide (InAs), or indium phosphide (InP). The semiconductor substrate 12 may include a conductive region such as a well doped with a dopant. The semiconductor substrate 12 may have various device isolation structures such as a shallow trench isolation (STI) structure therein.

The semiconductor device 14 including a plurality of individual devices of various types may be formed on the active surface of the semiconductor substrate 12. The individual devices may include various microelectronic devices: for example, a metal-oxide-semiconductor field effect transistor (MOSFET) such as a complementary metal-insulator-semiconductor transistor (CMOS); a system large-scale-integration (LSI) device; an image sensor such as a CMOS imaging sensor (CIS); a micro-electro-mechanical system (MEMS); an active device; a passive device; or the like. The individual devices may be electrically connected to the conductive region of the semiconductor substrate 12. The semiconductor device 14 may include at least two of the individual devices, or may further includes conductive wires or conductive plugs that electrically connect the individual devices to the conductive region of the semiconductor substrate 12. In addition, each of the individual devices may be electrically isolated from adjacent individual devices by an insulating layer.

The semiconductor chip 10 may be, for example, a central processing unit (CPU) chip, a graphic processing unit (GPU) chip, or an application processor (AP) chip. In some embodiments, when the packaged integrated circuit 1 includes a plurality of semiconductor chips 10, some of the semiconductor chips 10 may be, for example, dynamic random access memory (DRAM) chips, static random access memory (SRAM) chips, flash memory chips, electrically erasable and programmable read-only memory (EEPROM) chips, phase-change random access memory (PRAM) chips, magnetic random access memory (MRAM) chips, or resistive random access memory (RRAM) chips.

The semiconductor chip 10 may be mounted on the lower redistribution layer 100 by a flip-chip method. That is, the semiconductor chip 10 may be mounted on the lower redistribution layer 100 such that the active surface of the semiconductor substrate 12 may face the lower redistribution layer 100. The chip connection pads 16 of the semiconductor chip 10 electrically connected to the semiconductor device 14 may be electrically connected to the lower redistribution layer 100. A plurality of chip connection terminals 18 may be arranged between the chip connection pads 16 and some of a plurality of first upper pads 125 to electrically connect the semiconductor chip 10 to a plurality of first redistribution patterns 120. For example, the chip connection terminals 18 may be solder balls or bumps.

The lower redistribution layer 100 may also be referred to as a lower wiring structure, a first wiring structure, and/or a first redistribution layer, and the upper redistribution layer 200 may be referred to as an upper wiring structure, a second wiring structure and/or a second redistribution layer. As shown, the lower redistribution layer 100 may be disposed under the semiconductor chip 10, the extended layer 160, and the connection structures 162 and may redistribute the chip connection pads 16 of the semiconductor chip 10 to an external region. For example, the lower redistribution layer 100 may include a lower redistribution insulating layer 110 and the first redistribution patterns 120.

The lower redistribution insulating layer 110 may include an insulating material such as a photo-imageable dielectric (PID) resin and may further include photosensitive polyimide and/or an inorganic filler. The lower redistribution insulating layer 110 may have a multilayer structure according to a multilayer structure of the first redistribution patterns 120. However, for ease of illustration, FIG. 1A illustrates that the lower redistribution insulating layer 110 has a four-layer structure. When the lower redistribution insulating layer 110 has a multi-layer structure, the lower redistribution insulating layer 110 may include a single material or different materials. For example, a plurality of lower redistribution insulating layers 110 may be referred to as first to fourth lower redistribution insulating layers 110L1, 110L2, 110L3, and 110L4 in the order of vertical positions (Z-direction positions) away from external connection terminals 150. The first lower redistribution insulating layer 110L1 may be referred to as a lowermost lower redistribution insulating layer 110L1.

The first redistribution patterns 120 may transmit electrical signals and/or transfer heat in the packaged integrated circuit 1. The first redistribution patterns 120 may include a plurality of first lower pads 124, the first upper pads 125, a plurality of first redistribution line patterns 126, and a plurality of first conductive vias 128. For example, the first redistribution patterns 120 may include a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy thereof. However, the first redistribution patterns 120 are not limited thereto.

The first lower pads 124 may be arranged in a lower portion of the lower redistribution layer 100 and may electrically connect the lower redistribution layer 100 to the external connection terminals 150. Lower surfaces of the first lower pads 124 may directly in contact with the external connection terminals 150, and the first conductive vias 128 may be arranged on upper surfaces of the first lower pads 124. For example, a plurality of lowermost first conductive vias 128L may be arranged on the first lower pads 124. In the current specification, a lower surface of an element may refer to a surface of the element closest to an external connection terminal 150 in a vertical direction (Z direction), and an upper surface of the element may refer to a surface of the element that is opposite the lower surface of the element.

Each of the first lower pads 124 may include an upper under-bump metallization (UBM) layer 121 and a lower UBM layer 122. The upper UBM layer 121 may be disposed in the second lower redistribution insulating layer 110L2, and the lower UBM layer 122 may be disposed in the first lower redistribution insulating layer 110L1. That is, each of the upper UBM layer 121 and the lower UBM layer 122 may be disposed in different lower redistribution insulating layers 110, and the lower UBM layer 122 may be disposed in the lowermost lower redistribution insulating layer 110L1.

At least one of the first conductive vias 128 may be disposed on an upper surface of the upper UBM layer 121, and a lower surface of the upper UBM layer 121 may be in direct contact with an upper surface of the lower UBM layer 122. The upper surface of the lower UBM layer 122 may be in direct contact with the lower surface of the upper UBM layer 121, and a lower surface of the lower UBM layer 122 may be in direct contact with an upper surface of an external connection terminal 150. The first conductive via 128 disposed on the upper surface of the upper UBM layer 121 may be referred to as a lowermost first conductive via 128L.

The upper UBM layer 121 may have a first width W1 in a first horizontal direction (X direction), the upper surface of the lower UBM layer 122 may have a second width W2 in the first horizontal direction (X direction), and the lower surface of the lower UBM layer 122 may have a third width W3 in the first horizontal direction (X direction). In a vertical cross-sectional view, the upper UBM layer 121 may have an approximately rectangular shape. In the vertical cross-sectional view, the lower UBM layer 122 may have an inverted trapezoidal shape with the second width W2 being greater than the third width W3. The second width W2 may be greater than the third width W3 by about 5 micrometers to about 15 micrometers. The first width W1 may be less than the second width W2 and greater than the third width W3. For example, the first width W1 may range from about 180 micrometers to about 220 micrometers. The upper UBM layer 121 and the lower UBM layer 122 may be formed in one piece, and the centers of the upper UBM layer 121 and the lower UBM layer 122 may be aligned with each other in the vertical direction (Z direction).

In the vertical direction (Z direction), a sidewall of the upper UBM layer 121 may not be aligned with a sidewall of the upper surface of the lower UBM layer 122 and a sidewall of the lower surface of the lower UBM layer 122. In addition, the sidewall of the upper UBM layer 121 may be disposed inward on the upper surface of the lower UBM layer 122 more than the sidewall of the upper surface of the lower UBM layer 122 in horizontal directions (X direction and/or Y direction). The sidewall of the upper UBM layer 121 may be aligned with an inclined surface of the lower UBM layer 122 in the vertical direction (Z direction).

A seed layer 123 may be disposed on the sidewall of the lower UBM layer 122. That is, the seed layer 123 may be disposed between the sidewall of the lower UBM layer 122 and the lowermost lower redistribution insulating layer 110L1. In addition, the seed layer 123 may not be disposed on the sidewall of the upper UBM layer 121. In addition, the lower surface of the upper UBM layer 121 may entirely be in direct contact with the upper surface of the lower UBM layer 122. Both the sidewall and the lower surface of the upper UBM layer 121 may not be in contact with the seed layer 123.

The upper surface of the upper UBM layer 121 may have an approximately flat shape. A seed layer 123 may be disposed between the upper UBM layer 121 and the first conductive via 128 disposed on the upper UBM layer 121. A lower surface of the first conductive via 128 disposed on the upper UBM layer 121 may have an approximately flat shape. The seed layer 123 may be disposed on at least a portion of a lower surface of each of the first redistribution line patterns 126.

A first thickness T1, which is the thickness of the upper UBM layer 121 in the vertical direction (Z direction), may be substantially equal to a second thickness T2, which is the thickness of the lower UBM layer 122 in the vertical direction (Z direction). The first thickness T1 and/or the second thickness T2 may range from about 3 micrometers to about 7 micrometers. The second thickness T2 may be substantially equal to the thickness of the lowermost lower redistribution insulating layer 110L1 in the vertical direction (Z direction). That is, the thickness of the lowermost lower redistribution insulating layer 110L1 in the vertical direction (Z direction) may range from about 3 micrometers to about 7 micrometers. The vertical thickness of each of the lower redistribution insulating layers 110, except the lowermost lower redistribution insulating layer 110L1, may be greater than the second thickness T2. That is, the lowermost lower redistribution insulating layer 110L1 may have the smallest vertical thickness among the lower redistribution insulating layers 110.

The first upper pads 125 may be arranged in an upper portion of the lower redistribution layer 100 and may electrically connect the lower redistribution layer 100 to the semiconductor chip 10 and/or the connection structures 162. The first upper pads 125 may be arranged on the fourth lower redistribution insulating layer 110L4. Lower surfaces of the first upper pads 125 may be in direct contact with upper surfaces of some of the first conductive vias 128, and upper surfaces of the first upper pads 125 may respectively be in direct contact with lower surfaces of the chip connection terminals 18 and/or the connection structures 162.

A photosensitive insulating material may be subjected to an exposure process and a developing process to form the first redistribution line patterns 126 and the first conductive vias 128. In some embodiments, the first redistribution patterns 120 may be formed by depositing a metal or a metal alloy on a seed layer including titanium, titanium nitride, and/or titanium tungsten.

The first redistribution line patterns 126 may be arranged on at least one of an upper surface and a lower surface of the lower redistribution insulating layers 110. The first conductive vias 128 may penetrate through at least one of the lower redistribution insulating layers 110 and may respectively be in contact with some of the first redistribution line patterns. In some embodiments, at least some of the first redistribution line patterns 126 may respectively be formed in one piece with some of the first conductive vias 128. For example, a first redistribution line pattern 126 may be formed in one piece with a first conductive via 128, which is in contact with an upper surface of the first redistribution line pattern 126. The first redistribution patterns 120, which include the first redistribution line patterns 126 and the first conductive vias 128, may be formed by a plating method. For example, the first redistribution patterns 120 may be formed by a plating method such as immersion plating, electroless plating, or electroplating.

The first conductive vias 128 may transmit electrical signals and/or transfer heat in the packaged integrated circuit 1. The first conductive vias 128 may include a metal such as molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy thereof. However, the first conductive vias 128 are not limited thereto. A photosensitive insulating material may be subjected to an exposure process and a developing process to form the first conductive vias 128. In some embodiments, the first conductive vias 128 may have a tapered shape extending with a downwardly decreasing horizontal width. That is, the horizontal width of each the first conductive vias 128 may decrease in a vertical direction (negative Z direction) away from the semiconductor chip 10.

External connection pads (not shown) may be formed on the lower surfaces of the first lower pads 124, and the external connection terminals 150 may be arranged on the external connection pads. The external connection terminals 150 may be electrically connected to the semiconductor chip 10 through the first redistribution patterns 120 of the lower redistribution layer 100. The external connection terminals 150 may connect the packaged integrated circuit 1 to a main board of an electronic device on which the packaged integrated circuit 1 is mounted. The external connection pads may be solder balls, which include a conductive material such as a metallic material including at least one selected from tin (Sn), silver (Ag), copper (Cu), and aluminum (Al).

The external connection terminals 150 may have a fourth width W4 in the first horizontal direction (X direction). The fourth width W4 may be equal to or less than the third width W3 of the lower UBM layer 122. That is, the first width W1 of the upper UBM layer 121 may be greater than the third width W3 and the fourth width W4. The lowermost first conductive vias 128L may have a fifth width W5 in the first horizontal direction (X direction). The fifth width W5 may range from about 20 micrometers to about 200 micrometers. The horizontal width of the lowermost first conductive vias 128L may be equal to or greater than the horizontal width of the first conductive vias 128.

Although not shown in FIGS. 1A to 1C, a plurality of lowermost first conductive vias 128L may be arranged on one upper UBM layer 121. That is, a plurality of lowermost first conductive vias 128L may overlap one upper UBM layer 121 in the vertical direction (Z direction). As shown in FIG. 1A, the external connection terminals 150 arranged on a portion corresponding to a lower surface of the semiconductor chip 10 and a portion extending outward from the lower surface of the semiconductor chip 10 in the first horizontal direction (X direction) and a second horizontal direction (Y direction). As a result, the lower redistribution layer 100 may has a function of redistribute the external connection pads to a portion wider than the lower surface of the semiconductor chip 10.

The lower redistribution layer 100 may further include a first upper solder resist layer 132 disposed on an upper surface of the lower redistribution layer 100. The first upper solder resist layer 132 may cover an upper surface of at least one of the lower redistribution insulating layers 110 while exposing the first upper pads 125. In some embodiments, the first upper solder resist layer 132 may be formed by applying a solder mask insulation ink to upper and lower surfaces of at least one of the lower redistribution insulation layers 110 by a screen printing method or an inkjet printing method, and then curing the solder mask insulating ink with heat, UV, or IR. In some other embodiments, the first upper solder resist layer 132 is formed by: completely applying a photosensitive solder resist to the upper surface of the at least one of the lower redistribution insulating layers 110 by a screen printing method or a spray coating method, or bonding a film-type solder resist material by a laminating method; removing unnecessary portions through exposure and developing processes; and then curing the photosensitive solder resist or the film-type solder resist material with heat, UV or IR.

The extended layer 160 may include: the connection structures 162; and a filler member 164 surrounding the connection structures 162 and the semiconductor chip 10. The connection structures 162 may be apart from the semiconductor chip 10 in horizontal directions (X direction and/or Y direction) and may be arranged around the semiconductor chip 10. The connection structures 162 may penetrate the filler member 164 to electrically connect the lower redistribution layer 100 and the upper redistribution layer 200 to each other. Upper and lower ends of each of the connection structures 162 may respectively be connected to and in contact with one of a plurality of second conductive vias 228 of the upper redistribution layer 200 and one of the first upper pads 125 of the lower redistribution layer 100.

Each of the connection structures 162 may include a through-mold via (TMV), conductive solder, a conductive pillar, or at least one conductive bump. In some embodiments, each of the connection structures 162 may be formed by soldering, to each other, a lower portion attached to one of the first upper pads 125 of the lower redistribution layer 100 and an upper portion attached to one of the second conductive vias 228 of the upper redistribution layer 200 such that the lower portion and the upper portion may reflow by heat and form one body. The filler member 164 may include, for example, an epoxy mold compound (EMC).

The upper redistribution layer 200 may include an upper redistribution insulating layer 210 and second redistribution patterns 220. In addition, each of the second redistribution patterns 220 may include a second upper pad 224, a second redistribution line pattern 226, and a second conductive via 228. The upper redistribution insulating layer 210, the second upper pads 224, the second redistribution line patterns 226, and the second conductive vias 228 are respectively similar to the first redistribution insulating layer 210, the first upper pad 125, the first redistribution line patterns 126, and the first conductive vias 128, and thus descriptions thereof will be omitted.

The upper redistribution layer 200 may further include a second upper solder resist layer 232 disposed on an upper surface of the upper redistribution layer 200. The second upper solder resist layer 232 may be substantially the same as the first upper solder resist layer 132. In a packaged integrated circuit of the related art, the horizontal width of an upper UBM layer of a first lower pad of a lower redistribution layer is greater than the horizontal width of a lower UBM layer of the first lower pad of the lower redistribution layer, and thus stress generated in a lower portion of the lower redistribution layer is transmitted along an interface between a first lower redistribution insulating layer and a second lower redistribution insulating layer. In addition, the first lower redistribution insulating layer is thinner than each of the other lower redistribution insulating layers, the first lower redistribution insulating layer has relatively poor resistance to stress. Therefore, the reliability of the packaged integrated circuit of the related art is relatively low.

However, in the packaged integrated circuit 1 of the inventive concept, the horizontal width of the upper UBM layer 121 is less than the horizontal width of the lower UBM layer 122, and thus stress generated in a lower portion of the packaged integrated circuit 1 is not transmitted along a boundary of the lowermost lower redistribution insulating layer 110L1. Therefore, the packaged integrated circuit 1 of the inventive concept may have relatively high resistance to stress. That is, the reliability of the packaged integrated circuit 1 of the inventive concept is relatively high.

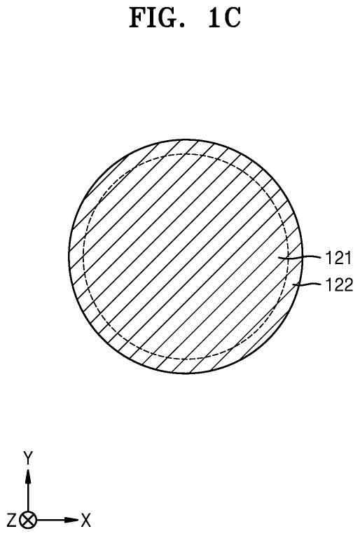

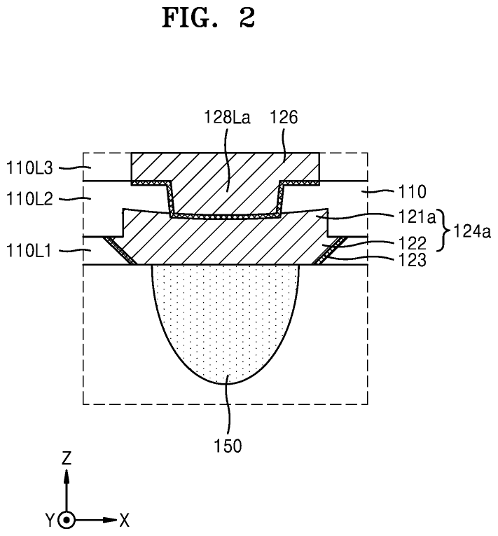

FIG. 2 is an enlarged cross-sectional view illustrating the portion A in FIG. 1A according to embodiments. A first lower pad 124a shown in FIG. 2 may include an upper UBM layer 121a and a lower UBM layer 122. The lower UBM layer 122 shown in FIG. 2 is substantially the same as the lower UBM layer 122 shown in FIG. 1B, and thus only the upper UBM layer 121a will be described here. Referring to FIG. 2, an upper surface of the upper UBM layer 121a may not be flat but may have a concave shape recessed in a vertically downward direction. In other words, the upper surface of the upper UBM layer 121a may have a concave shape recessed in a direction toward an external connection terminal 150. A lower surface of a lowermost first conductive via 128La disposed on the upper UBM layer 121a may have a convex shape protruding in a vertically downward direction. That is, the lower surface of the lowermost first conductive via 128La disposed on the upper UBM layer 121a may have a convex shape protruding toward the external connection terminal 150.

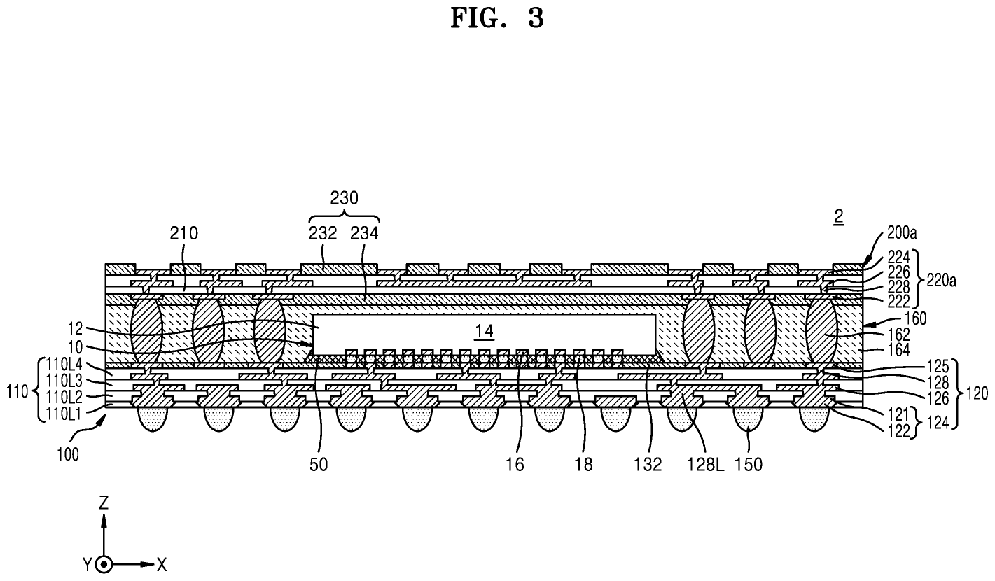

FIG. 3 is a cross-sectional view illustrating a packaged integrated circuit 2 according to embodiments. Referring to FIG. 3, the packaged integrated circuit 2 may include a lower redistribution layer 100, connection structures 162, and an upper redistribution layer 200a. In addition, the packaged integrated circuit 2 may include a second upper solder resist layer 232 and a second lower solder resist layer 234, which are respectively arranged on an upper surface and a lower surface of the upper redistribution layer 200a.

The second upper solder resist layer 232 may surround and protect second upper pads 224, and the second lower solder resist layer 234 may surround and protect second lower pads 222. The second upper solder resist layer 232 and the second lower solder resist layer 234 may form a second solder resist layer 230.

In addition, an underfill layer 50 may be disposed between a semiconductor chip 10 and the lower redistribution layer 100 to surround chip connection terminals 18. The underfill layer 50 may include, for example, an epoxy resin and may be formed by a capillary underfill method. In some embodiments, the underfill layer 50 may cover at least a portion of a sidewall of the semiconductor chip 10.

For example, each of the connection structures 162 may include conductive solder. The upper redistribution layer 200a may include an upper redistribution insulating layer 210 and second redistribution patterns 220a. In addition, second redistribution patterns 220a may include the second lower pads 222, the second upper pads 224, second redistribution line patterns 226, and second conductive vias 228. The connection structures 162 may respectively be in direct contact with the second lower pads 222 of the upper redistribution layer 200a for physical and/or electrical connection therebetween.

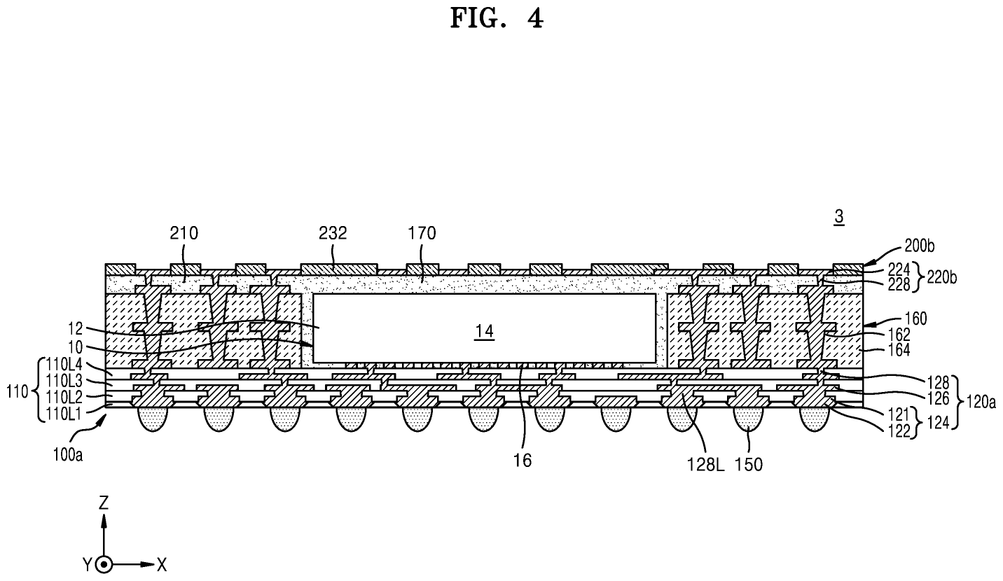

FIG. 4 is a cross-sectional view illustrating a packaged integrated circuit 3 according to embodiments. Referring to FIG. 4, the packaged integrated circuit 3 may include a lower redistribution layer 100a, connection structures 162, and an upper redistribution layer 200b. The lower redistribution layer 100a may include a plurality of first lower pads 124, a plurality of first redistribution line patterns 126, and a plurality of first conductive vias 128.

For example, each of the connection structures 162 may be copper foil of an embedded trace substrate (ETS). Although FIG. 4 illustrates an example in which each of the connection structures 162 has three layers, the technical spirit and scope of the inventive concept are not limited thereto. A person of ordinary skill in the art may use an ETS having one, two, or four or more layers based on the description of the inventive concept.

When copper foil of a ETS is selected as the connection structures 162, the packaged integrated circuit 3 may additionally include a molding layer 170. The upper redistribution layer 200b may be formed on an upper surface of the molding layer 170. The upper redistribution layer 200b may include multi-layered copper wires for electrical connection with the copper foil of the ETS. The upper redistribution layer 200b may include an upper redistribution insulating layer 210 and second redistribution patterns 220b. The second redistribution patterns 220b may include a plurality of second upper pads 224 and a plurality of second conductive vias 228.

Chip pads 16 of a semiconductor chip 10 and the connection structures 162 may be connected to portions of the lower redistribution layer 100a while making direct contact with the portions of the lower redistribution layer 100a. For example, the chip pads 16 of the semiconductor chip 10 and the connection structures 162 may be connected to some of the first conductive vias 128 by direct contact therebetween.

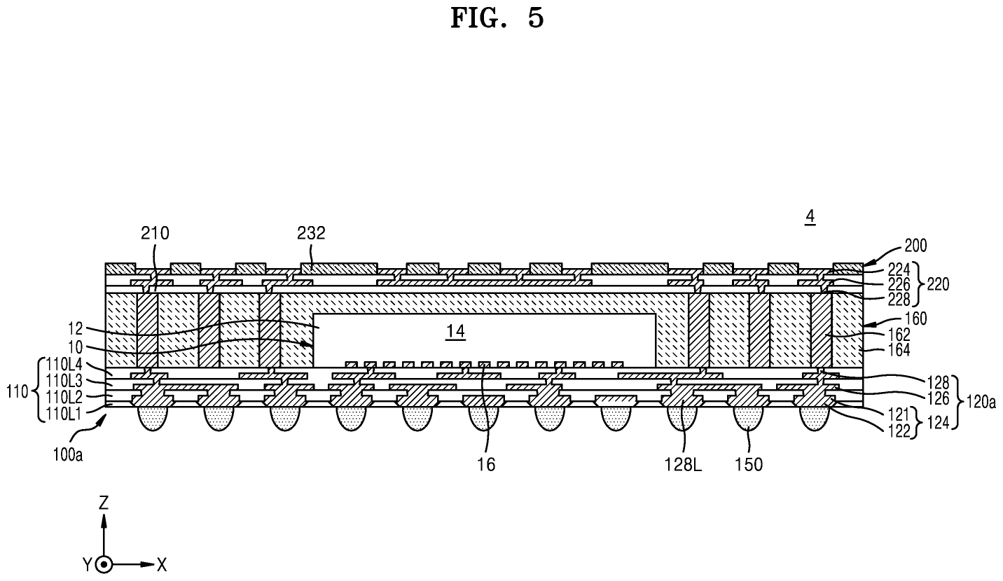

FIG. 5 is a cross-sectional view illustrating a packaged integrated circuit 4 according to embodiments. Referring to FIG. 5, the packaged integrated circuit 4 may include a lower redistribution layer 100a, connection structures 162, and an upper redistribution layer 200. The lower redistribution layer 100a may include a plurality of first lower pads 124, a plurality of first redistribution line patterns 126, and a plurality of first conductive vias 128.

Chip pads 16 of a semiconductor chip 10 and the connection structures 162 may be connected to portions of the lower redistribution layer 100a while making direct contact with the portions of the lower redistribution layer 100a. For example, the chip pads 16 of the semiconductor chip 10 and the connection structures 162 may be connected to some of the first conductive vias 128 by direct contact therebetween.

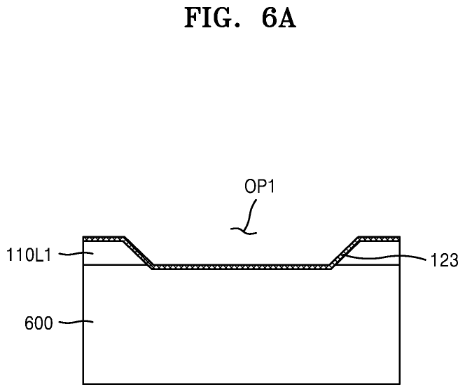

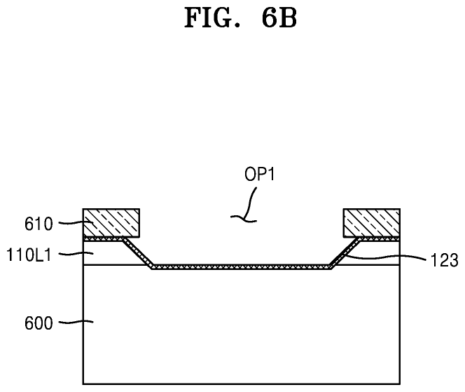

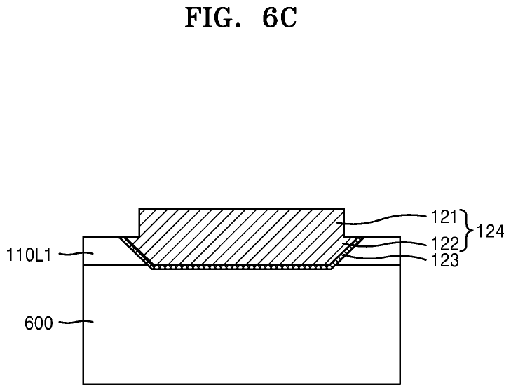

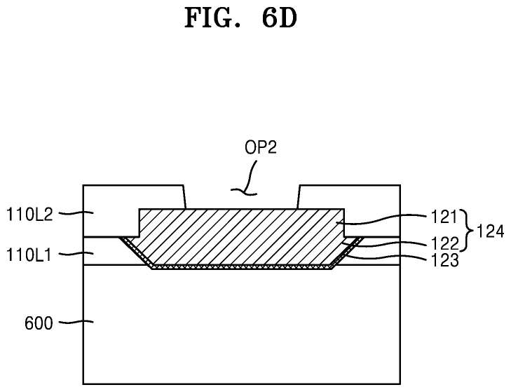

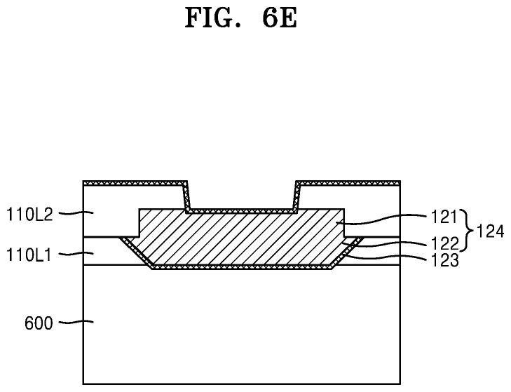

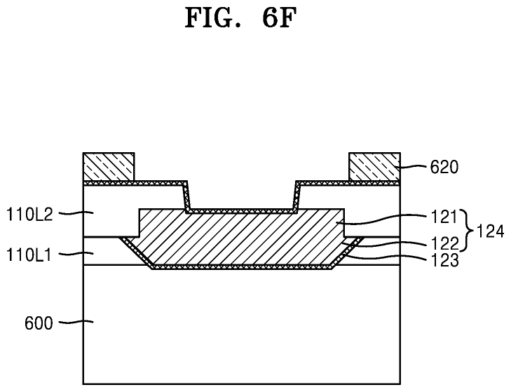

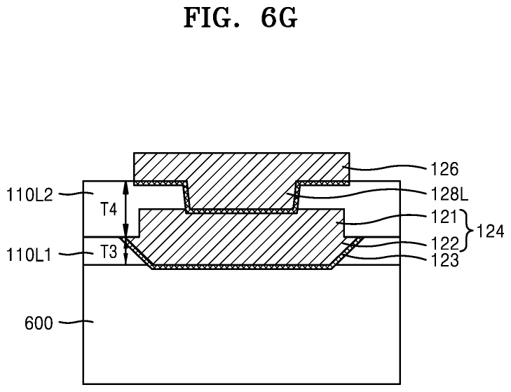

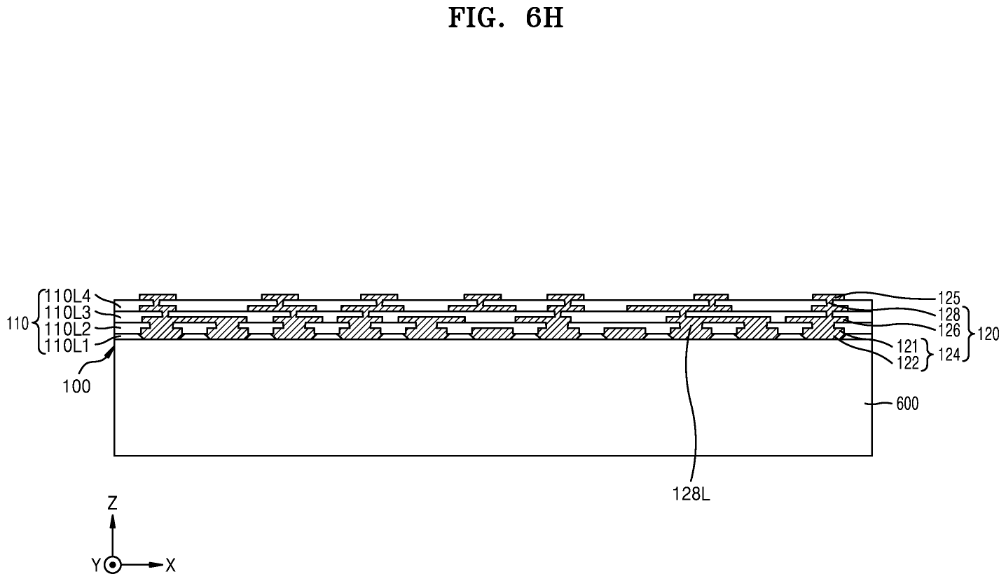

FIGS. 6A to 6H are cross-sectional views illustrating a method of manufacturing a packaged integrated circuit according to embodiments. Referring to FIG. 6A, a first lower redistribution insulating layer 110L1 may be formed by attaching a preliminary first lower redistribution insulating layer (not shown) to a support carrier 600, and forming a first opening OP1. The first opening OP1 may have an inverted trapezoidal shape in which the width of an upper surface of the first opening OP1 is greater than the width of a lower surface of the first opening OP1. A lower UBM layer (refer to the lower UBM layer 122 shown in FIG. 1B) may be formed later in the first opening OP1. In addition, the first lower redistribution insulating layer 110L1 may be coated with a seed layer 123. A first redistribution pattern (refer to the first redistribution patterns 120 shown in FIG. 1A) may be formed by depositing a metal or a metal alloy on the seed layer 123.

Referring to FIG. 6B, the first lower redistribution insulating layer 110L1 may be coated with a photoresist layer 610. A sidewall of the photoresist layer 610 may be aligned with a sidewall of the first lower redistribution insulating layer 110L1 in a vertical direction (Z direction). Another sidewall of the photoresist layer 610 may overlap the first opening OP1 in a vertical direction (Z direction). For example, the other sidewall of the photoresist layer 610 may be aligned with an inclined surface of the first opening OP1 in the vertical direction (Z direction). In addition, the other sidewall of the photoresist layer 610 may not be aligned with the lower surface of the first opening OP1 in the vertical direction (Z direction). In the vertical direction (Z direction), the other sidewall of the photoresist layer 610 may be aligned with a region between a sidewall of the lower surface of the first opening OP1 and a sidewall of the upper surface of the first opening OP1.

Referring to FIG. 6C, an upper UBM layer 121 and a lower UBM layer 122 may be formed in a space defined by the first opening OP1 and the photoresist layer 610 (refer to FIG. 6B). The upper UBM layer 121 and the lower UBM layer 122 may be formed by depositing a metal or a metal alloy on the seed layer 123. After the upper UBM layer 121 and the lower UBM layer 122 are formed, the first lower redistribution insulating layer 110L1 may be exposed by etching the photoresist layer 610 (refer to FIG. 6B). The seed layer 123 may not be disposed on the uppermost surface of the first lower redistribution insulating layer 110L1. Although not shown in FIG. 6C, when an upper surface of the upper UBM layer 121 has a concave shape recessed in a vertically downward direction (refer to the upper UBM layer 121a shown in FIG. 2), the first lower pad 124a shown in FIG. 2 may be formed.

Referring to FIG. 6D, a preliminary second lower redistribution insulating layer (not shown) may be attached to the first lower redistribution insulating layer 110L1 to cover an upper surface of the first lower redistribution insulating layer 110L1, a portion of an upper surface of the lower UBM layer 122, and a sidewall and an upper surface of the upper UBM layer 121. In the vertical direction (Z direction), the thickness of the preliminary second lower redistribution insulating layer may be greater than the thickness of the first lower redistribution insulating layer 110L1.

Thereafter, a second lower redistribution insulating layer 110L2 may be formed by forming a second opening OP2 in the preliminary second lower redistribution insulating layer to expose a portion of the upper surface of the upper UBM layer 121. The second opening OP2 may have an inverted trapezoidal shape in which the width of an upper surface of the second opening OP2 is greater than the width of a lower surface of the second opening OP2. A first conductive via (refer to the first conductive via 128 shown in FIG. 1B) may be formed later in the second opening OP2.

Referring to FIG. 6E, an upper surface and an inner sidewall of the second lower redistribution insulating layer 110L2, and the exposed portion of the upper surface of the upper UBM layer 121 may be coated with a seed layer 123. A first redistribution pattern (refer to the first redistribution patterns 120 shown in FIG. 1A) may be formed by depositing a metal or a metal alloy on the seed layer 123.

Referring to FIG. 6F, the second lower redistribution insulating layer 110L2 may be coated with a second photoresist layer 620. A sidewall of the second photoresist layer 620 may be aligned with a sidewall of the second lower redistribution insulating layer 110L2 in the vertical direction (Z direction). Another sidewall of the second photoresist layer 620 may not overlap the second opening OP2 in the vertical direction (Z direction).

Referring to FIG. 6G, a first redistribution line pattern 126 and a lowermost first conductive via 128L may be formed in a space defined by the second opening OP2 and the second photoresist layer 620 (refer to FIG. 6F). The first redistribution line pattern 126 and the lowermost first conductive via 128L may be formed by depositing a metal or a metal alloy on the seed layer 123. After the first redistribution line pattern 126 and the lowermost first conductive via 128L are formed, the second photoresist layer 620 (refer to FIG. 6F) may be etched to expose the second lower redistribution insulating layer 110L2. The seed layer 123 may be disposed on a portion of the uppermost surface of the second lower redistribution insulating layer 110L2 but may not be disposed on the other portion of the uppermost surface of the second lower redistribution insulating layer 110L2. The seed layer 123 may be disposed on the uppermost surface of the second lower redistribution insulating layer 110L2 in a region overlapping the lowermost first conductive via 128L in the vertical direction (Z direction), but may not be disposed on the uppermost surface of the second lower redistribution insulating layer 110L2 in a region not overlapping the lowermost first conductive via 128L in the vertical direction (Z direction).

A third thickness T3, which is the thickness of the first lower redistribution insulating layer 110L1 in the vertical direction (Z direction), may be less than a fourth thickness T4, which is the thickness of the second lower redistribution insulating layer 110L2 in the vertical direction (Z direction). For example, the third thickness T3 may be about 3 micrometers to about 7 micrometers, and the fourth thickness T4 may be about 6 micrometers to about 14 micrometers.

Referring to FIG. 6H, a lower redistribution layer 100 may be formed on the resultant structure shown in FIG. 6G by repeating a plurality of times the processes described with reference to FIGS. 6D to 6G. In each first lower pad 124 of the lower redistribution layer 100, the horizontal width of the upper UBM layer 121 may be less than the horizontal width of the lower UBM layer 122.

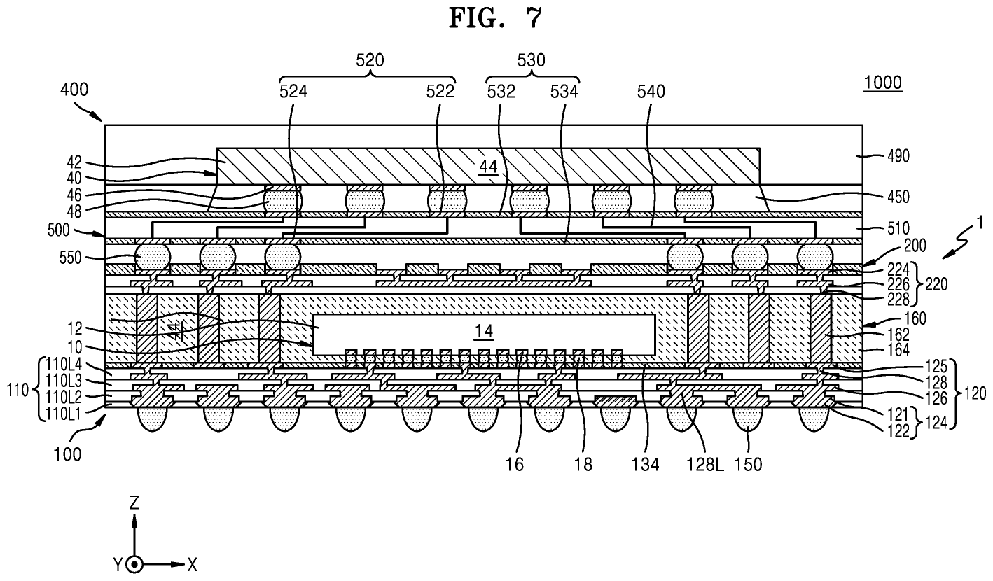

FIGS. 7 to 10 are cross-sectional views illustrating package-on-packages 1000, 1000a, 1000b, and 1000c having packaged integrated circuits according to embodiments. Referring to FIG. 7, the package-on-package 1000 includes a second packaged integrated circuit 400 disposed on a first packaged integrated circuit 1. The first packaged integrated circuit 1 may be a lower packaged integrated circuit, and the second packaged integrated circuit 400 may be an upper packaged integrated circuit. The first packaged integrated circuit 1, a first semiconductor chip 10, a first semiconductor substrate 12, a first semiconductor device 14, first chip connection pads 16, and first chip connection terminals 18 are substantially the same as the packaged integrated circuit 1, the semiconductor chip 10, the semiconductor substrate 12, the semiconductor device 14, the chip connection pads 16, and the chip connection terminals 18 described with reference to FIGS. 1A to 1C, and thus descriptions thereof will be omitted.

The second packaged integrated circuit 400 may include at least one second semiconductor chip 40. The second packaged integrated circuit 400 may be electrically connected to the first packaged integrated circuit 1 through a plurality of package connection terminals 550 attached to a plurality of second upper pads 224 of the first packaged integrated circuit 1 that are exposed without being covered with a second upper pad 224.

The at least one second semiconductor chip 40 may include: a second semiconductor substrate 42 having a second semiconductor device 44 formed on an active surface of the second semiconductor substrate 42; and a plurality of second chip connection pads 46 arranged on the active surface of the second semiconductor substrate 42. The second semiconductor substrate 42, the second semiconductor device 44, and the second chip connection pads 46 are substantially similar to the semiconductor substrate 12, the semiconductor device 14, and the chip connection pads 16 described with reference to FIGS. 1A to 1C, and thus overlapping descriptions thereof will be omitted. The at least one second semiconductor chip 40 may be a memory semiconductor chip. The at least one second semiconductor chip 40 may be, for example, a DRAM chip, an SRAM chip, a flash memory chip, an EEPROM chip, a PRAM chip, an MRAM chip, or an RRAM chip.

Although FIG. 7 illustrates that the at least one second semiconductor chip 40 of the second packaged integrated circuit 400 is mounted on a package base substrate 500 by a flip-chip method, this is a non-limiting example. The package-on-package 1000 may include any type of packaged integrated circuit as an upper packaged integrated circuit as long as the packaged integrated circuit includes at least one second semiconductor chip 40 and the package connection terminals 550 are attachable to a lower side of the packaged integrated circuit for electrical connection with the first packaged integrated circuit 1.

The package base substrate 500 may include a base board layer 510 and a plurality of board pads 520 arranged on upper and lower surfaces of the base board layer 510. The board pads 520 may include a plurality of upper board pads 522 arranged on the upper surface of the base board layer 510 and a plurality of lower board pads 524 arranged on the lower surface of the base board layer 510. In some embodiments, the package base substrate 500 may be a printed circuit board. For example, the package base substrate 500 may be a multi-layer printed circuit board. The base board layer 510 may include at least one material selected from a phenol resin, an epoxy resin, and polyimide.

A board solder resist layer 530 exposing the board pads 520 may be formed on the upper and lower surfaces of the base board layer 510. The board solder resist layer 530 may include: an upper board solder resist layer 532 covering the upper surface of the base board layer 510 while exposing the upper board pads 522; and a lower board solder resist layer 534 covering the lower surface of the base board layer 510 while exposing the lower board pads 524.

The package base substrate 500 may include board wiring 540, which electrically connect the upper board pads 522 and the lower board pads 524 to each other inside the base board layer 510. The board wiring 540 may include board wiring lines and board wiring vias. The board wiring 540 may include, nickel, stainless steel, or beryllium copper. In some embodiments, the board wiring 540 be disposed between the upper surface of the base board layer 510 and the upper board solder resist layer 532, and/or between the lower surface of the base board layer 510 and the lower board solder resist layer 534.

The upper board pads 522 may be electrically connected to the second semiconductor chip 40. For example, a plurality of second chip connection terminals 48 may be arranged between the second chip connection pads 46 of the second semiconductor chip 40 and the upper board pads 522 of the package base substrate 500 to electrically connect the second semiconductor chip 40 and the package base substrate 500 to each other. In some embodiments, a second underfill layer 450 surrounding the second chip connection terminals 48 may be disposed between the second semiconductor chip 40 and the package base substrate 500. For example, the second underfill layer 450 may include an epoxy resin and may be formed by a capillary underfill method. In some embodiments, the second underfill layer 450 may be a non-conductive film.

An upper molding layer 490 surrounding the second semiconductor chip 40 may be disposed on the package base substrate 500. The upper molding layer 490 may include, for example, an epoxy mold compound (EMC). In some embodiments, the upper molding layer 490 may cover an inactive surface of the second semiconductor chip 40. In some other embodiments, the upper molding layer 490 may cover a sidewall of the second semiconductor chip 40 but may not cover the non-active surface of the second semiconductor chip 40, and a heat dissipation member may be attached to the non-active surface of the second semiconductor chip 40.

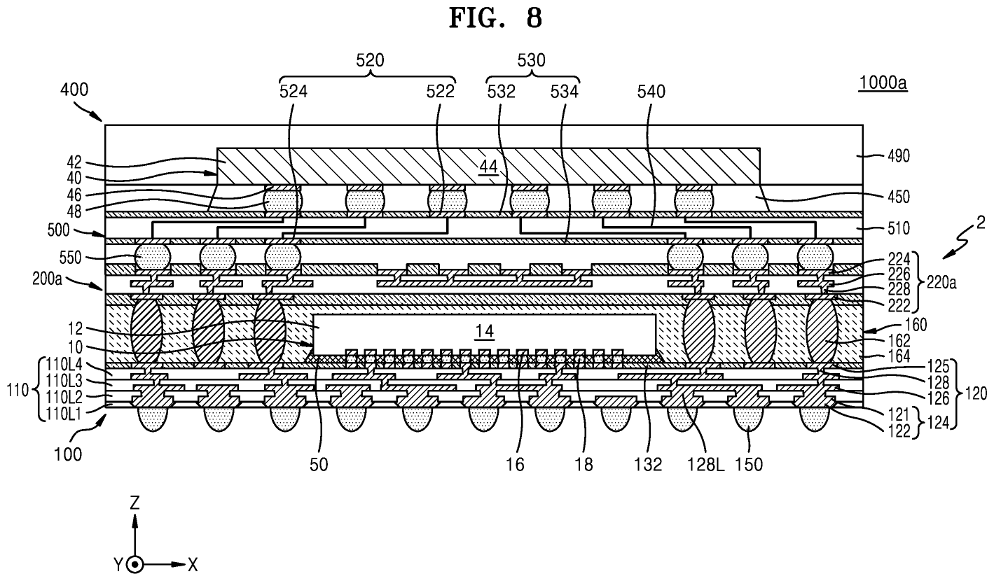

Referring to FIG. 8, the package-on-package 1000a includes a second packaged integrated circuit 400 disposed on a first packaged integrated circuit 2. The first packaged integrated circuit 2 may be a lower packaged integrated circuit, and the second packaged integrated circuit 400 may be an upper packaged integrated circuit. The first packaged integrated circuit 2 is substantially the same as the packaged integrated circuit 2 described with reference to FIG. 3, and the second packaged integrated circuit 400 is substantially the same as the second packaged integrated circuit 400 described with reference to FIG. 7. Thus, descriptions thereof will be omitted.

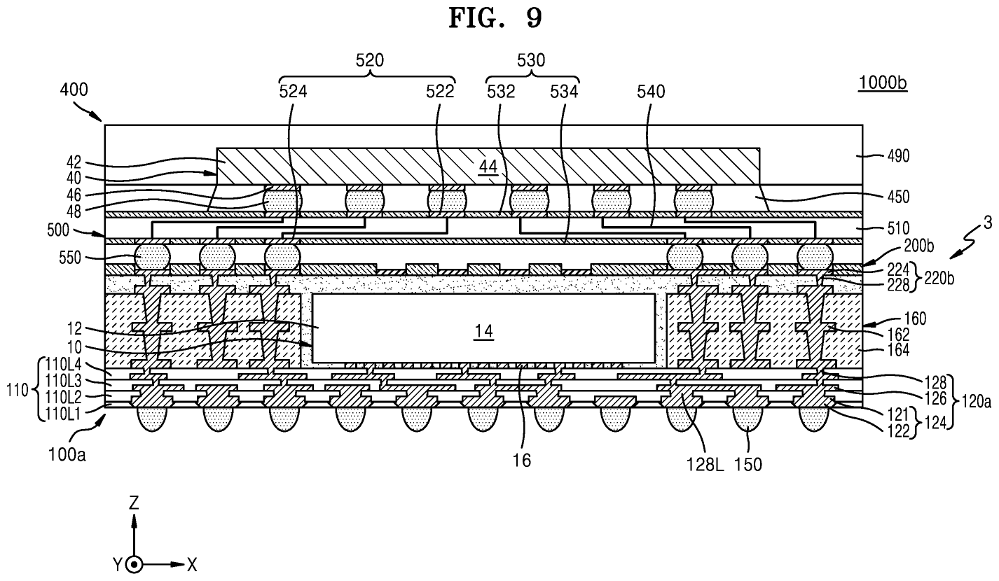

Referring to FIG. 9, the package-on-package 1000b includes a second packaged integrated circuit 400 disposed on a first packaged integrated circuit 3. The first packaged integrated circuit 3 may be a lower packaged integrated circuit, and the second packaged integrated circuit 400 may be an upper packaged integrated circuit. The first packaged integrated circuit 3 is substantially the same as the packaged integrated circuit 3 described with reference to FIG. 4, and the second packaged integrated circuit 400 is substantially the same as the second packaged integrated circuit 400 described with reference to FIG. 7. Thus, descriptions thereof will be omitted.

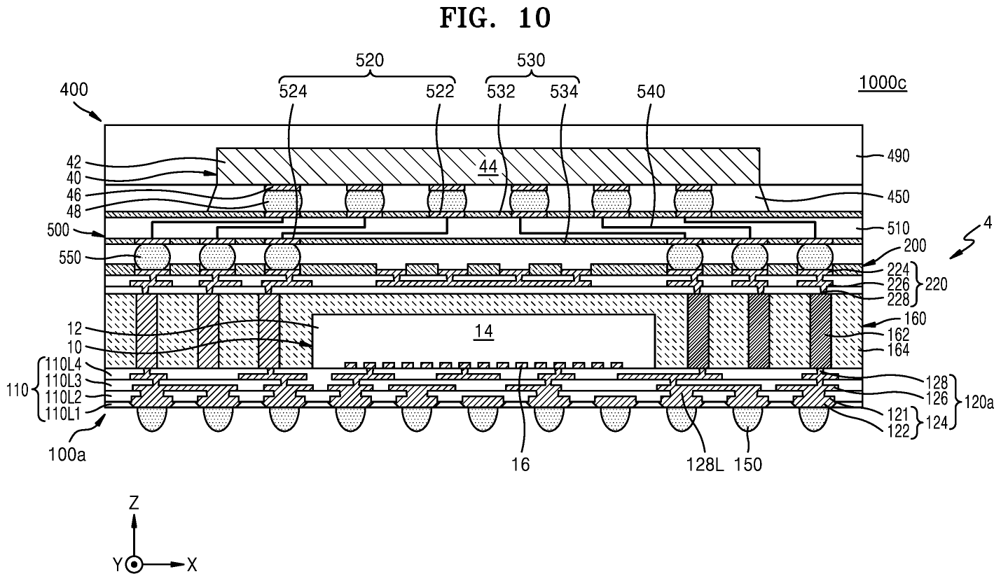

Referring to FIG. 10, the package-on-package 1000c includes a second packaged integrated circuit 400 disposed on a first packaged integrated circuit 4. The first packaged integrated circuit 4 may be a lower packaged integrated circuit, and the second packaged integrated circuit 400 may be an upper packaged integrated circuit. The first packaged integrated circuit 4 is substantially the same as the packaged integrated circuit 4 described with reference to FIG. 5, and the second packaged integrated circuit 400 is substantially the same as the second packaged integrated circuit 400 described with reference to FIG. 7. Thus, descriptions thereof will be omitted.

While the inventive concept has been particularly shown and described with reference to embodiments thereof, it will be understood that various changes in form and details may be made therein without departing from the spirit and scope of the following claims.

What is claimed is:

1. A packaged integrated circuit, comprising:
a redistribution layer including a plurality of electrically conductive vias extending at least partially therethrough, and a plurality of lower pads electrically connected to corresponding ones of the plurality of electrically conductive vias;
a semiconductor chip on the redistribution layer; and
external connection terminals electrically contacting corresponding ones of the plurality of lower pads within the redistribution layer;
wherein each of the plurality of lower pads includes: (i) a lower under-bump metallization (UBM) layer in contact with a corresponding external connection terminal, and (ii) an upper UBM layer extending on and contacting the lower UBM layer; and
wherein an upper surface of the lower UBM layer has a greater lateral width dimension relative to an upper surface of the upper UBM layer, which contacts a corresponding electrically conductive via.

2. The packaged integrated circuit of claim 1, wherein the lower UBM layer has a sidewall that is slanted when viewed from a cross-sectional perspective such that a width of the lower UBM layer adjacent an interface with the corresponding external connection terminal is less than a width of the lower UBM layer adjacent an interface with the corresponding upper UBM layer.

3. The packaged integrated circuit of claim 1, wherein a lateral width dimension of the upper surface of the upper UBM layer is greater than the width of the lower UBM layer adjacent an interface with the corresponding external connection terminal.

4. The packaged integrated circuit of claim 1, wherein the upper surface of the upper UBM layer is planar.

5. The packaged integrated circuit of claim 1, wherein the upper surface of the upper UBM layer has a concave shape that is recessed in a direction of the corresponding external connection terminal.

6. The packaged integrated circuit of claim 1, wherein a lateral width dimension of the upper surface of the upper UBM layer is greater than or equal to a maximum lateral width dimension of the corresponding external connection terminal.

7. The packaged integrated circuit of claim 1, wherein a center of the upper UBM layer is vertically aligned to a center of the lower UBM layer.

8. A packaged integrated circuit, comprising:
a redistribution layer including a plurality of conductive lines, a plurality of electrically conductive vias connected to the plurality of conductive lines, a plurality of lower pads electrically connected to the plurality of electrically conductive vias, and a plurality of redistribution insulating layers;
an integrated circuit chip on the redistribution layer; and
a plurality of external connection terminals attached to the plurality of lower pads in the redistribution layer;
wherein each of the plurality of lower pads is embedded within a lowermost redistribution insulating layer of the plurality of redistribution insulating layers, and extends between a corresponding one of the plurality of conductive vias and a corresponding one of the plurality of external connection terminals;
wherein each of the plurality of lower pads comprises a lower under-bump metallization (UBM) layer that contacts one of the plurality of external connection terminals, and an upper UBM layer extending on the lower UBM layer; and
wherein an upper surface of the lower UBM layer has a greater than or equivalent lateral width dimension relative to an upper surface of the upper UBM layer.

9. The packaged integrated circuit of claim 8,
wherein a portion of the upper surface of the lower UBM layer is in contact with a lower surface of the upper UBM layer; and
wherein a remaining portion of the upper surface of the lower UBM layer is in contact with at least one of the plurality of redistribution insulating layers.

10. The packaged integrated circuit of claim 8,
wherein a seed layer is provided between a sidewall of the lower UBM layer and a lowermost one of the plurality of redistribution insulating layers; and
wherein a sidewall of the upper UBM layer is in contact with at least one of the plurality of redistribution insulating layers.

11. The packaged integrated circuit of claim 8, wherein a seed layer is provided on a sidewall and on a lower surface of an electrically conductive via extending on the upper UBM layer.

12. The packaged integrated circuit of claim 8, wherein when viewed from a cross-sectional perspective, an outer wall of the upper UBM layer is not vertically aligned with an outer wall of the upper surface of the lower UBM layer, but is disposed inward on the upper surface of the lower UBM layer to a greater extent than the outer wall of the upper surface of the lower UBM layer in a horizontal direction.

13. The packaged integrated circuit of claim 8, wherein the upper UBM layer and the lower UBM layer are contiguous.

14. A packaged integrated circuit, comprising:
a first redistribution layer including a plurality of first conductive lines, a plurality of first conductive vias electrically connected to corresponding ones of the plurality of first conductive lines, a plurality of first lower pads electrically connected to corresponding ones of the plurality of first conductive vias, and a plurality of lower redistribution insulating layers;
a semiconductor chip on the first redistribution layer;
connection structures, which are arranged on the first redistribution layer and spaced apart from the semiconductor chip in a horizontal direction;
a second redistribution layer extending on the connection structures, said second redistribution layer including a plurality of second conductive lines and a plurality of second conductive vias electrically connected to corresponding ones of the plurality of second conductive lines; and
a plurality of external connection terminals attached to the plurality of first lower pads of the first redistribution layer;
wherein each of the plurality of first lower pads extends within a lowermost lower redistribution insulating layer of the plurality of lower redistribution insulating layers, and between one of the plurality of first conductive vias and one of the plurality of external connection terminals;
wherein each of the plurality of first lower pads includes a lower under-bump metallization (UBM) layer provided in contact with one of the plurality of external connection terminals and an upper UBM layer disposed on the lower UBM layer;
wherein the lower UBM layer has a tapered shape with a downwardly decreasing horizontal width as measured between slanted sidewalls thereof; and
wherein a first width, which is a horizontal width of the upper UBM layer, is equal to or less than a second width, which is a horizontal width of an upper surface of the lower UBM layer.

15. The packaged integrated circuit of claim 14, wherein the first width is equal to or greater than each of a third width, which is a horizontal width of a lower surface of the lower UBM layer, and a fourth width, which is a horizontal width of each of the plurality of external connection terminals.

16. The packaged integrated circuit of claim 15, wherein the second width and the third width are different from each other by about 5 micrometers to about 20 micrometers.

17. The packaged integrated circuit of claim 14, wherein an upper surface of the upper UBM layer has a flat shape or a concave shape that is recessed in a vertical downward direction toward at least one of the plurality of external connection terminals.

18. The packaged integrated circuit of claim 14, wherein a lower surface of the upper UBM layer is entirely in direct contact with the upper surface of the lower UBM layer.

19. The packaged integrated circuit of claim 18, wherein the first width ranges from about 150 micrometers to about 250 micrometers; and wherein the upper UBM layer has a height of about 2 micrometers to about 8 micrometers.

20. The packaged integrated circuit of claim 14, wherein the connection structures each include one selected from a through-mold via (TMV), conductive solder, a conductive pillar, and a conductive bump.
